(19) United States
(12) Patent Application Publication
(10) Pub. No.: US 2025/0379083 A1
(43) Pub. Date: Dec. 11, 2025

(54) METHOD AND SYSTEM FOR UPSAMPLING MEASUREMENT POINT OF SEMICONDUCTOR MANUFACTURING PROCESS, AND METHOD FOR TRAINING UPSAMPLING MODEL

(71) Applicant: Samsung Electronics Co., Ltd., Suwon-si (KR)

(72) Inventors: Ha Chul SHIN, Suwon-si (KR); Il Hwan KIM, Suwon-si (KR); Mu Young LEE, Suwon-si (KR); Ik Jun JANG, Suwon-si (KR); Hee Sun JUN, Suwon-si (KR); Sang Ho JO, Suwon-si (KR)

(21) Appl. No.: 18/971,524

(22) Filed: Dec. 6, 2024

(30) Foreign Application Priority Data
Jun. 7, 2024 (KR) 10-2024-0074496

(51) Int. Cl. H01L 21/68; H01L 21/66

(52) U.S. Cl. CPC H01L 21/68; H01L 22/12

(57) ABSTRACT

A method of upsampling measurement points in a semiconductor process includes obtaining a first dataset including first measurement points, first measurement values, and first variables, generating a second dataset based on the first dataset, and inputting the second dataset into an upsampling model to estimate second measurement values of second measurement points. The first variables include a numeric variable, an ordinal variable, and a categorical variable related to the plurality of first measurement values. Second variables of the second data set include a numeric variable, an ordinal variable, and a categorical variable related to the second measurement values.

### CROSS-REFERENCE TO RELATED APPLICATION

This application claims priority from Korean Patent Application No. 10-2024-0074496 filed on Jun. 7, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a method and system for upsampling measurement points of a semiconductor manufacturing process, and a method of training a upsampling model. More specifically, the present disclosure relates to a method of upsampling measurement data on a low-density measurement point to generate measurement data on a high-density measurement point, and a method of training an upsampling model.

### Description of Related Art

Lithography technology plays a key role in manufacturing of an integrated circuit (IC) and other semiconductor devices. The lithography process involves forming a pattern on a substrate having a photosensitive material referred to as a photoresist coated thereon. Typically, the pattern is formed using a mask or a reticle Light is irradiated to the substrate through the mask or the reticle, such that a selected area of the resist is exposed or protected. The exposed area is then removed or left through a developing process. Thus, a desired pattern is formed on the substrate.

Accuracy and uniformity of the lithography process are critical to device performance and reliability. However, during the manufacturing process, various factors may affect the performance of the lithographic process. For example, substrate deformation, resist thickness change, light scattering, and many other factors may affect pattern formation. To correct an effect thereof and optimize the lithographic process, various measurement and correction techniques are used in the manufacturing process.

In conventional lithography processes, pattern measurements are mainly performed only at specific measurement points at which special patterns often referred to as metrology targets are formed. However, these targets are not uniformly distributed across the entire substrate, and measurement data are obtained only at limited measurement points. With such limited measurement points, it is difficult to fully figure out the overall performance of the lithography process, and a portion requiring correction may be missed or inappropriate correction may be made. Recently, a density of the measurement points required is increasing due to the advancement of correction technology. However, high-density target measurement is limited due to a lack of measurement facilities.

To solve these problems, a technology for upsampling the measurement data on the measurement points has recently been proposed. This technology creates higher density measurement points based on existing measurement data. Thus, the overall performance of the lithography process may be more accurately determined, and the portion requiring correction may be accurately identified and appropriate correction may be performed.

### SUMMARY

A technical purpose sought to be achieved using an embodiment of the present disclosure is to provide a method of upsampling measurement data of low-density measurement points to generate measurement data of high-density measurement points.

Furthermore, a technical purpose sought to be achieved using an embodiment of the present disclosure is to provide a method of training a machine learning model for upsampling measurement data of low-density measurement points using a plurality of measurement data as training data.

Furthermore, a technical purpose sought to be achieved using an embodiment of the present disclosure is to provide a method of improving correction performance using an upsampling result in an overlay measurement process during the semiconductor manufacturing process.

According to an aspect of the present disclosure, a method of upsampling measurement points in a semiconductor process comprises obtaining a first dataset including a plurality of first measurement points, a plurality of first measurement values corresponding to the plurality of first measurement points, and a plurality of first variables representing information of the semiconductor process other than the plurality of first measurement values, generating a second dataset based on the first dataset, wherein the second dataset includes a plurality of second measurement points and a plurality of second variables, wherein the plurality of second measurement points are different from the plurality of first measurement points, and inputting the second dataset into an upsampling model to estimate a plurality of second measurement values corresponding to the plurality of second measurement points. The plurality of second variables represent information of the semiconductor process other than the plurality of second measurement values. The plurality of first variables include a numeric variable, an ordinal variable, and a categorical variable related to the plurality of first measurement values. The plurality of second variables include a numeric variable, an ordinal variable, and a categorical variable related to the plurality of second measurement values. The method is performed by a computing device.

According to an aspect of the present disclosure, a method of training an upsampling model for upsampling measurement points in a semiconductor process obtaining a plurality of datasets, wherein each of the plurality of datasets includes a plurality of measurement points, a plurality of measurement values corresponding to the plurality of measurement points, and a plurality of variables representing information of the semiconductor process other than the plurality of measurement values, and training the upsampling model to estimate a measurement value corresponding to any measurement point, using the plurality of datasets as training data. The plurality of datasets are related to the semiconductor process. The plurality of variables include a numeric variable, an ordinal variable, and a categorical variable related to the plurality of measurement values. The method is performed by a computing device.

According to an aspect of the present disclosure, a system for upsampling measurement points in a semiconductor process includes a processor and a memory for storing instructions therein. When the instructions are executed by the processor, the instructions cause the processor to obtain a first dataset including a plurality of first measurement points, a plurality of first measurement values corresponding to the plurality of first measurement points, and a plurality of first variables other than the plurality of first measurement values, generate a second dataset based on the first dataset, wherein the second dataset includes a plurality of second measurement points and a plurality of second variables, wherein the plurality of second measurement points are different from the plurality of first measurement points, and input the second dataset into an upsampling model to estimate a plurality of second measurement values corresponding to the plurality of second measurement points. The plurality of second variables represent information of the semiconductor process other than the plurality of second measurement values. The plurality of first variables include a numeric variable, an ordinal variable, and a categorical variable related to the plurality of first measurement values. The plurality of second variables include a numeric variable, an ordinal variable, and a categorical variable related to the plurality of second measurement values.

Specific details of other embodiments are included in detailed descriptions and drawings.

### BRIEF DESCRIPTION OF DRAWINGS

The above and other aspects and features of the present disclosure will become more apparent by describing in detail embodiments thereof with reference to the attached drawings, in which:

FIG. 1 is a block diagram showing an example configuration of a computing system for performing a semiconductor manufacturing process according to an embodiment of the present disclosure;

FIG. 2 conceptually shows high-density measurement, low-density measurement, and upsampling according to an embodiment of the present disclosure;

FIG. 3 is a flowchart illustrating a method of training an upsampling model according to an embodiment of the present disclosure;

FIG. 4 shows a difference between an actual measurement result and an upsampling result based on a type of training data used in the upsampling model.

FIG. 5 shows performance of the upsampling model based on the type of the training data;

FIG. 6 shows feature importance of the upsampling model based on the type of the training data;

FIG. 7 is a flowchart illustrating a method of upsampling measurement points according to an embodiment of the present disclosure.

FIG. 8 shows a result of re-measurement after correction based on each of low-density measurement, high-density measurement, and measurement point upsampling per wafer; and

FIG. 9 shows a difference in correction performance based on the remeasurement result in FIG. 8.

### DETAILED DESCRIPTIONS

Hereinafter, embodiments of the present disclosure will be described in detail with reference to the attached drawings. Advantages and features of the present disclosure, and a method of achieving the advantages and features will become apparent with reference to embodiments described later in detail together with the accompanying drawings. However, embodiments of the present disclosure are not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure the gist of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. The terminology used herein is directed to the purpose of describing particular embodiments only and is not intended to limit the present disclosure. As used herein, the singular constitutes “a” and “an” are intended to include the plural constitutes as well, unless the context clearly indicates otherwise.

Additionally, in describing the components of the present disclosure, terms such as first, second, A, B, a, and b may be used. These terms are only used to distinguish one component from another component, and the nature, sequence, order, or number of the component are not limited by the term. It should be understood that when a component is described as being “connected,” “coupled,” or “combined” to another component, the component may be directly connected, coupled, or combined to another component, still another component may be “interposed” therebetween, and thus the component may be connected, coupled, or combined to another component via the sill another component.

It will be further understood that the terms “comprise”, “comprising”, “include”, and “including” as used herein specify the presence of the stated features, steps, operations, elements, and/or components, but do not preclude the presence or addition of one or more other features, steps, operations, elements, components, and/or portions thereof.

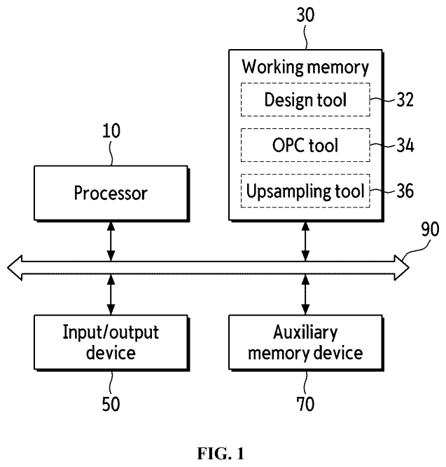

FIG. 1 is a block diagram showing an example configuration of a computing system for performing a semiconductor manufacturing process according to an embodiment of the present disclosure.

Referring to FIG. 1, the computing system may include a processor 10, a working memory 30, an input/output device 50, and an auxiliary memory device 70. The computing system in FIG. 1 may be provided as a dedicated device for creating and correcting an optical proximity correction (OPC) model, and may be equipped with various design and verification simulation programs. The present disclosure is not limited thereto. For example, the computing system of FIG. 1 may be implemented with using a general computer equipped with various design and verification simulation programs.

The processor 10 may execute software (application programs, operating systems, device drivers) in the computing system. The processor 10 may execute an operating system (OS, not shown) loaded into the working memory 30. The processor 10 may execute various application programs based on the operating system (OS). For example, the processor 10 may execute layout design tool 32 and/or optical proximity correction (OPC) tool 34 loaded into the working memory 30. The processor 10 may be configured to include at least one of a Central Processing Unit (CPU), a Micro Processor Unit (MPU), a Micro Controller Unit (MCU), a Graphics Processing Unit (GPU), or any type of processor well known in the art of the present disclosure.

The operating system (OS) or the application programs may be loaded into the working memory 30. When the computing system is booted, an OS image (not shown) stored in the auxiliary memory device 70 may be loaded into the working memory 30 based on a boot sequence. All input/output operations of the computing system may be supported by the operating system (OS). The application programs may be loaded into the working memory 30 as selected by the user or to provide basic services. The design tool 32, the OPC tool 34, and/or an upsampling tool 36 may be loaded into the working memory 30 from the auxiliary memory device 70.

The design tool 32 may be equipped with a bias function that may change a shape and a location of specific layout patterns to be different from those as defined by a design rule. The design tool 32 may perform a design rule check (DRC) under a changed bias data condition. The OPC tool 34 may perform OPC on layout data output from the design tool 32.

The upsampling tool 36 may include an upsampling model as a machine learning model for performing the upsampling of measurement points according to the embodiment of the present disclosure. The upsampling tool 36 may secure information, measurement points, and measurement values about the semiconductor manufacturing process to create a new dataset, or fetch a dataset related to an existing semiconductor manufacturing process. The upsampling tool 36 may train the upsampling model to estimate a measurement value on any measurement point using the newly created dataset and the existing dataset as training data. For example, the dataset may be a dataset related to overlay measurement during the semiconductor manufacturing process. In the overlay measurement, the alignment of layers formed on a substrate may be measured to quantify how well the layers of a semiconductor device are aligned. The overlay measurement may ensure that the patterns in each layer are aligned correctly and that there is no misalignment between layers. The data from the overlay measurement is used to improve a photolithography process and the overall performance of the semiconductor device. The overlay measurement and correction are discussed in U.S Publications US20240310720, US20220179302, and US20230074537, the entirety of each of which is incorporated by reference herein. However, the present disclosure is not limited thereto.

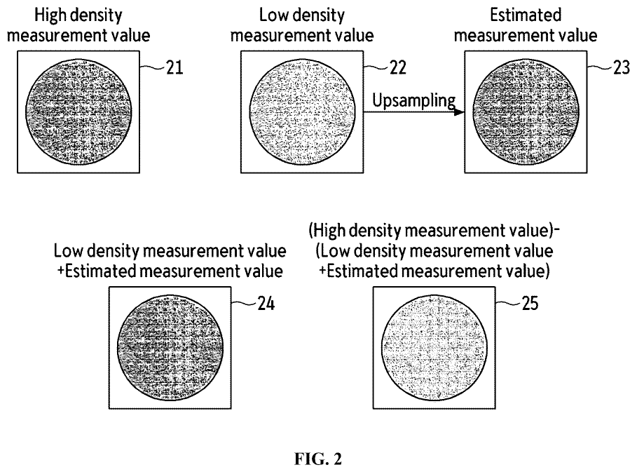

Furthermore, the upsampling tool 36 may input a virtual dataset into the trained upsampling tool to estimate virtual measurement values to upsample low-density measurement points into high-density measurement points. Afterwards, the upsampling tool 36 may generate various correction values and residuals on the semiconductor manufacturing process, using the measurement points generated as the upsampling result together with the actual measurement points, and may use the generated various correction values and residuals to control the process. Embodiments related to training of the upsampling model and upsampling of the measurement points using the upsampling model are described later with reference to FIGS. 2 to 9.

For example, the working memory 30 may be embodied as a volatile memory such as dynamic random access memory (DRAM) or static random access memory (SRAM), or a non-volatile memory such as flash memory, phase change random access memory (PRAM), resistance random access memory (RRAM), nano floating gate memory (NFGM), polymer random access memory (PoRAM), magnetic random access memory (MRAM), ferroelectric random access memory (FRAM), etc.

The input/output device 50 controls user input and output from user interface devices.

For example, the input/output device 50 may include a keyboard or a monitor to receive information from a designer. Using the input/output device 50, the designer may receive information about data paths or a semiconductor area requiring adjusted operating characteristics. A processing process and a processing result of the OPC tool 34 and/or the upsampling tool 36 may be displayed through the input/output device 50.

The auxiliary memory device 70 is provided as a storage medium of the computing system. The auxiliary memory device 70 may store therein application programs, operating system images, and various data. The auxiliary memory device 70 may be embodied as a memory card (MMC, eMMC, SD, MicroSD, etc.) or a hard disk drive (HDD). The auxiliary memory device 70 may include NAND flash memory having a large storage capacity. Alternatively, the auxiliary memory device 70 may include other nonvolatile memories such as PRAM, MRAM, ReRAM, or FRAM, or NOR flash memory.

A system interconnector 90 may be a system bus for providing a network within the computing system. Through the system interconnector 90, the processor 10, the working memory 30, the input/output device 50, and the auxiliary memory device 70 may be electrically connected with each other and may exchange data with each other. However, a configuration of the system interconnector 90 is not limited to the above description, and the system interconnector 90 may further include relay means for efficient management.

FIG. 2 conceptually shows high-density measurement, low-density measurement, and upsampling according to an embodiment of the present disclosure. Referring to FIG. 2, first, a measurement value 21 of the actual high-density measurement point and the measurement value 22 of the low-density measurement point are shown. It may be identified that the high-density measurement has a larger number of measurement points than measurement points in the low-density measurement. When measurement values are measured at the larger number of measurement points, the correction accuracy of the semiconductor manufacturing process may be higher. However, actually performing the high-density measurement requires a large number of measurement equipment, and may take a lot of time. Therefore, instead of actually obtaining measurement values from high-density measurement points, it may be effective to generate high-density measurement points based on a result of upsampling the low-density measurement points and to estimate the measurement values of the generated measurement points.

Referring to FIG. 2, the measurement values 23 estimated at the high-density measurement points obtained by upsampling the low-density measurement points according to an embodiment of the present disclosure is shown. For example, the estimated measurement values 23 may be a result obtained by inputting a dataset including the measurement values 22 of the low-density measurement point and related variables into the upsampling model. Afterwards, integrated measurement values 24 may be obtained by integrating the measurement values 22 of the low-density measurement points and the measurement values 23 estimated at the high-density measurement points generated by the upsampling thereof. Based on a difference 25 between the integrated measurement values 24 and the actual measurement values 21 of the high-density measurement points, it may be identified that a difference between the measurement values estimated at the high-density measurement points as created by upsampling the low-density measurement point and the actual the measurement values of the high-density measurement point is not large. In other words, it may be identified that the method of upsampling the measurement point according to an embodiment of the present disclosure exhibits excellent effectiveness.

For reference, the high-density measurement may be referred to as high-resolution measurement, and the low-density measurement may be referred to as low-resolution measurement. That is, the high density (high resolution) and the low density (low resolution) may be determined based on the number of measurement points in the same space. Furthermore, inputting the dataset into the upsampling model may include inputting the measurement point, the measurement value corresponding to the measurement point, and a plurality of variables related to the measurement value included in the dataset. In general, the density of measurement points in the dataset output as a result of the upsampling may be higher than the density of measurement points in the dataset input to the upsampling model.

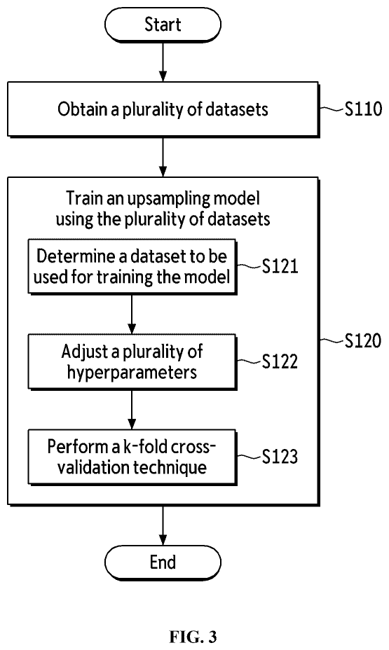

Hereinafter, embodiments related to a method of training an upsampling model and a method of upsampling measurement points using the trained upsampling model will be described. First, referring to FIGS. 3 to 6, the method of training the upsampling model is described.

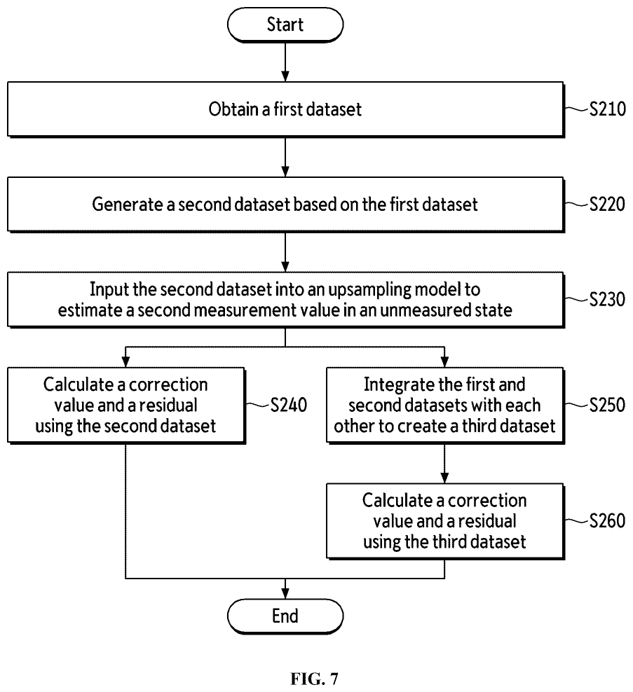

FIG. 3 is a flowchart illustrating the method of training the upsampling model according to an embodiment of the present disclosure. For reference, FIG. 3, and FIG. 7, which will be described later, show steps/operations of the upsampling model training method or the upsampling method as performed in the computing system of FIG. 1. Therefore, in the following descriptions, it may be appreciated that when a subject of a specific step/operation is omitted, the specific step/operation is performed in the computing system in FIG. 1.

In step S110, a plurality of datasets may be acquired, and each of the plurality of datasets may include a plurality of measurement points, a measurement value of each of the plurality of measurement points, and a plurality of variables other than the measurement value. The acquired plurality of datasets may be datasets related to a current semiconductor manufacturing process or may be datasets related to a previous semiconductor manufacturing process. The plurality of datasets may be stored on a semiconductor process basis, and the plurality of datasets used for training the upsampling model may be related to the same semiconductor process.

The plurality of variables other than the measurement value may include numeric variables, ordinal variables, and categorical variables related to the measurement value. In some embodiments, the plurality of variables may represent information related to a semiconductor process other than the measurement value. Specifically, in estimating the measurement value of any measurement point, not only numeric variables such as the actual location of the measurement point and the actual measurement value thereof, but also categorical variables and ordinal variables such as substrate exposure information and process information of the substrate may be used together in training of the upsampling model to improve the performance of the upsampling model.

For example, the numeric variables related to the measurement value include a measurement position on the substrate, a position of the exposure field, a substrate leveling value at the measurement position, and a Z2XY value obtained using a differential value of the leveling value. For example, the Z2XY value could be determined using Z2XY model, which determines distortion induced overlay from leveling data and aberration sensitivities (which can be calculated using lithographical simulations). The ordinal variables may include a field exposure order, a substrate exposure order, etc. The categorical variables may include measurement date, product, exposure layer, exposure date, exposure equipment name, measurement equipment name, substrate ID, exposure direction, field row number, and field column number, measurement direction, etc. However, the present disclosure is not limited thereto, and the numeric variables, ordinal variables, and categorical variables may include other variables that may affect the measurement value in addition to the variables as described above. In other words, the upsampling model according to an embodiment of the present disclosure may receive not only the measurement value but also other variables related to the measurement value and may train the upsampling model based on the received value and variables to estimate the measurement value more accurately.

Then, in step S120, the upsampling model for estimating a measurement value corresponding to any measurement point may be trained using the acquired plurality of datasets. For example, the upsampling model may be trained to estimate a measurement value corresponding to any measurement point using a decision tree algorithm and a light gradient boosting machine (LGBM) algorithm on the plurality of datasets.

Specifically, in step S121, the dataset to be used for training the model among the plurality of acquired datasets may be determined. The total number of datasets used for training the model may directly affect the performance of the upsampling model. The performance of the upsampling model may be expected to improve as a larger amount of datasets are used. For example, among the acquired n (n is a natural number) datasets, the currently measured dataset and m (m is a natural number) previous datasets related to the same semiconductor process as that related to the currently measured dataset may be used.

In step S122, a plurality of hyperparameters of the upsampling model may be adjusted. The hyperparameters may be preset through simulation or may be adjusted using at least one of gird search, random search, and Bayesian search. Then, in step S123, a k-fold cross-validation technique may be performed on the determined dataset to prevent overfitting by machine learning. Within the determined dataset, k combinations of training sets and validation sets may be created, and the average of the measurement values predicted on the combinations may be used as a final prediction result of the upsampling model. The k in the k-fold cross-validation technique may be preset like the hyperparameters, or may be flexibly adjusted depending on the characteristics of the dataset used for training the model. For example, k-fold cross-validation may be a way to assess the upsampling model's performance by splitting the determined dataset into k equally sized subsets (or “folds”). The process goes as follows: 1) the upsampling model is trained on (k−1) folds and validated on the remaining fold; 2) this is repeated k times, each time using a different fold as the validation set and the rest as the training set; and 3) the performance metric across all folds is averaged to get a more robust estimate of the upsampling model's performance. The performance metric may be a measure used to evaluate howe well the upsampling model is performing. For example, the performance metric may quantify the accuracy or effectiveness of the estimation of the upsampling model. For example, the performance metric may include M3S (mean+3SD) value corresponding to an overlay error resulting from the overlay correction, which will be described in detail below.

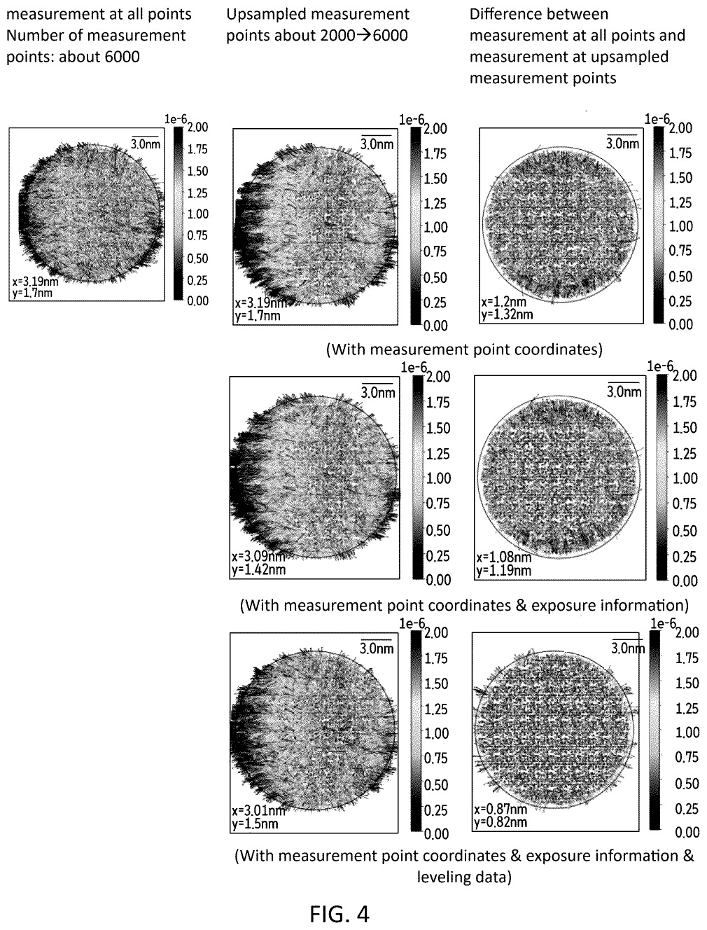

FIG. 4 shows the difference between the actual measurement result and the upsampling result based on a type of the training data used in the upsampling model. For example, the measurement points as shown in FIG. 4 may be measurement points related to overlay measurement. Referring to FIG. 4, the measurement values measured at about 6000 total measurement points, the predicted measurement values at the measurement points generated through the upsampling, and the differences between the actual measurement values and the predicted measurement values are sequentially shown. In this regard, it is assumed that the dataset containing about 2000 measurement points has been upsampled through the upsampling model so as to include about 6000 measurement points.

In this regard, the predicted measurement values at the measurement points generated through the upsampling, and the difference between the actual measurement value and the predicted measurement value are shown in each of a case when the upsampling model is trained using only measurement point coordinate information, a case when the upsampling model is trained using the measurement point coordinate information and exposure information, and a case when the upsampling model is trained using measurement point coordinate information, exposure information, and leveling data are shown. Referring to FIG. 4, it may be identified that the difference is reduced when the model is trained using both the exposure information and the measurement point coordinate information, compared to when the model is trained using only the measurement point coordinate information. It may be identified that the difference is the smallest when the model is trained using the exposure information, the measurement point coordinate information, and the leveling data.

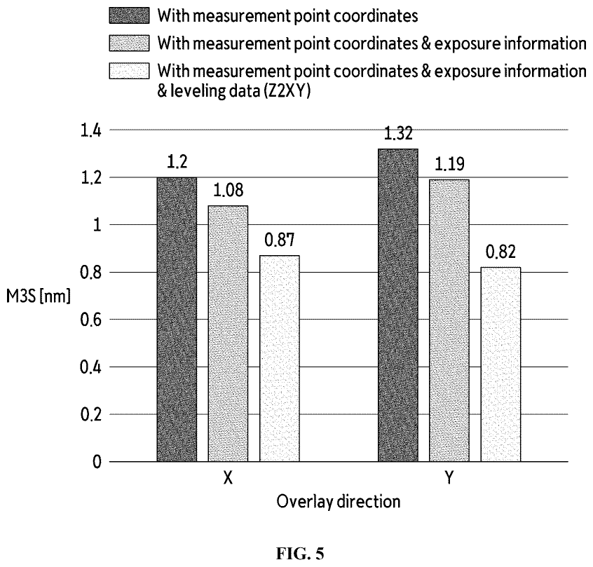

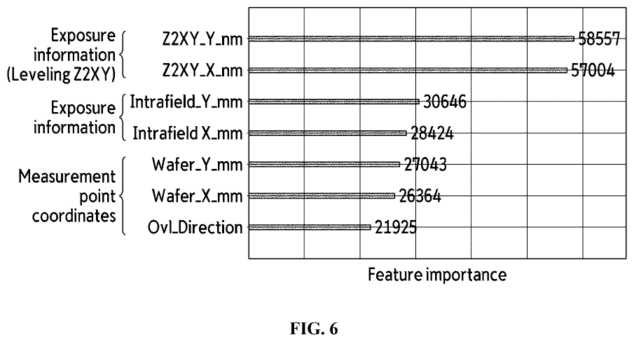

The smaller the difference between the actual measurement value and the predicted measurement value, the higher the estimation accuracy of the upsampling model. Therefore, it may be identified that the upsampling model is most accurately trained using all of the measurement point coordinate information, the exposure information, and the leveling data. This is described in more detail with reference to FIGS. 5 to 6.

FIG. 5 shows the performance of the upsampling model based on the type of the training data. Referring to FIG. 5, as shown in FIG. 4, in each of a case when the model is trained using only measurement point coordinate information, a case when the model is trained using the measurement point coordinate information and the exposure information, a case when the model is trained using the measurement point coordinate information, the exposure information, and the leveling data (Z2XY value), a M3S (mean+3SD) value as a performance indicator of overlay correction using the measurement point generated through the upsampling, is shown. In some embodiments, the overlay correction may be a process that fixes misalignments between patterns of the current and previous exposure layers in photolithography, and the residual may be non-correctable components in the overlay correction. The smaller the M3S value, the higher the overlay correction performance.

Therefore, referring to FIG. 5, it may be identified that the performance of the correction is the highest when the overlay correction is performed using the measurement point generated through the upsampling model trained using all of the measurement point coordinate information, exposure information, and leveling data (Z2XY value). In other words, it may be identified that when the upsampling model is trained using measurement point coordinate information as a numeric variable, exposure information as a categorical variable, and leveling data (Z2XY value) as a numeric variable related to exposure information, the performance of the model is higher compared to the case where only measurement point coordinate information as a numeric variable is used to train the model.

FIG. 6 shows the feature importance of the upsampling model based on the type of the training data. The feature importance is a value that represents a level that contributes to the training of a machine learning model. For example, the feature importance may be calculated based on mean decrease impurity (MDI) when each variable is partitioned in the decision tree. The accuracy of the model may be recalculated while removing each feature one by one. The feature importance may be calculated based on the level of each feature contributing to accuracy (drop-column importance). Referring to an example of FIG. 6, the leveling data (Z2XY value) as a numeric variable among the exposure information has the greatest feature importance, followed by the exposure information (intrafield_Y_mm, intrafield_X_mm) excluding the leveling data, followed by the measurement point coordinate information (wafer_Y_mm, wafer_X_mm, ovl_direction). Therefore, it may be identified that the performance of the upsampling model is higher when the upsampling model is trained using the measurement point coordinate information, the actual measurement values, the exposure information and other variables together, compared to the case when the upsampling model is trained using only the measurement point coordinate information and the actual measurement values.

Now, referring to FIGS. 7 to 9, a method of upsampling the measurement points using the upsampling model trained according to the method in FIG. 3 will be described.

FIG. 7 is a flowchart illustrating a method of upsampling measurement points according to an embodiment of the present disclosure.

In step S210, a first dataset including a plurality of first measurement points, a first measurement value of each of the plurality of first measurement points, and a plurality of first variables other than the first measurement value may be obtained. In other words, the first dataset may refer to a dataset including the measurements which have been obtained by actually measuring the measurement points, and may be a dataset related to a semiconductor manufacturing process currently in progress. The plurality of first variables may include a plurality of numeric variables, ordinal variables, and categorical variables as described with reference to FIG. 3.

In step S220, based on the first dataset as an actual dataset, a second dataset including a plurality of second measurement points, and a plurality of second variables other than a second measurement value at each of the second measurement points may be created. That is, the second dataset may be a virtual dataset that has a measurement point that is different from that of the first dataset. In this virtual dataset, the measurement value at the second measurement point is not measured but estimated. Like the plurality of first variables, the plurality of second variables may include a plurality of numeric variables, ordinal variables, and categorical variables. Even when the measurement value at the second measurement point is not measured, the plurality of second variables may be determined based on the information on the semiconductor manufacturing process. For example, the plurality of second variables may be determined to be the same as the plurality of first variables. Furthermore, the plurality of second measurement points may be measurement points having a higher density (or higher resolution) than that of the plurality of first measurement points.

In an embodiment in which the first dataset and the second dataset are related to overlay measurement, example types of variables that the plurality of first variables and the plurality of second variables may include may be the same as those as described with reference to FIG. 3. Therefore, descriptions thereof will be omitted.

In step S230, the second dataset may be input to the upsampling model, and the second measurement value in an unmeasured state may be estimated. The upsampling model may be a model that has been pre-trained using the actual dataset according to the training method in FIG. 3. In other words, the upsampling model may receive not only the coordinate information of the measurement point of the second dataset and but also the plurality of all types of second variables and may estimate the unmeasured measurement value based on the received information and the variables.

Thereafter, correction may be performed on the semiconductor manufacturing process using only the upsampled second dataset, or using the first dataset and the upsampled second dataset together. Specifically, in step S240, the correction value and a residual may be calculated using only the second dataset. On the other hand, in step S250, the first and second datasets may be integrated with each other to create a third dataset, and in step S260, a correction value and a residual may be calculated using the third dataset. In embodiments where the first dataset and the second dataset are datasets related to overlay measurement, the correction value and a residual may correspond to the overlay correction value and residual.

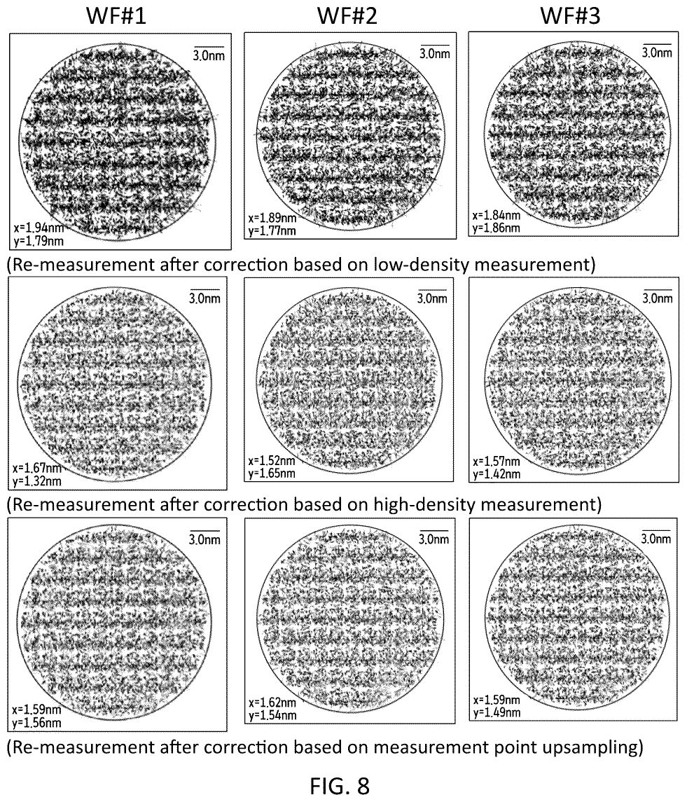

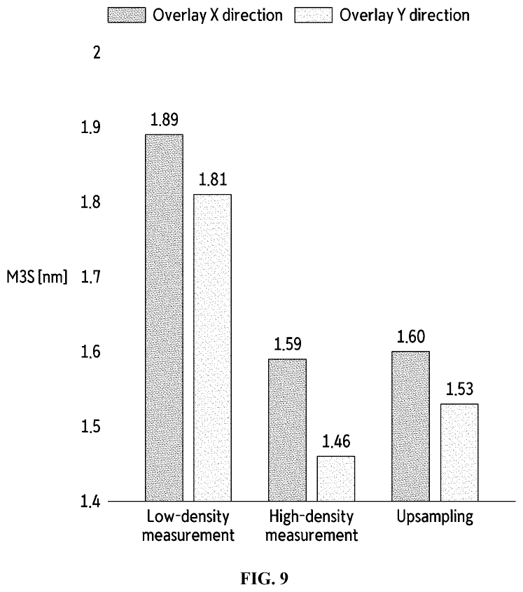

According to the above-described embodiments, advanced correction on the semiconductor manufacturing process may be made by estimating the measurement values at the high-density measurement points via the upsampling of the low-density measurement points. This is described in more detail with reference to FIGS. 8 to 9.

FIG. 8 shows a result of re-measurement after correction based on each of low-density measurement, high-density measurement, and measurement point upsampling per wafer. FIG. 8 shows the re-measurement result after overlay correction has been performed based on the actual measurement values of the low-density measurement points on each of the three wafers (WF #1,WF #2, WF #3); the re-measurement result after overlay correction has been performed based on the actual measurement value of the high-density measurement points on each of the three wafers (WF #1, WF #2, WF #3); and the re-measurement result after overlay correction has been performed based on the measurement value estimated via the upsampling of the low-density measurement point. Thus, the difference between correction performance based on the actual measurement values of the high-density measurement points and correction performance based on the measurement value estimated the upsampling is described with reference to FIG. 9.

FIG. 9 shows the difference in correction performance based on the remeasurement result in FIG. 8. Referring to FIG. 9, the average of the M3S value as the performance indicators of overlay correction calculated on each wafer in FIG. 8 is shown in each of a case when the correction is made based on low-density measurement, a case when the correction is made based on high-density measurement, and a case when correction is made based on the upsampling result of the measurement point. In fact, it may be identified that there is almost no difference between the performance when the correction is made based on the high-density measurement and the performance when the correction is made based on the upsampling result of low-density measurement points. In other words, according to an embodiment of the present disclosure, the actual measurement is performed only on low-density measurement points, so that the time required for measurement may be shortened, and correction performance may be improved to a level equivalent to correction performance based on the actual high-density measurement.

Further, the method of upsampling the measurement points and the method of training the upsampling model according to an embodiment of the present disclosure may be executed in the computing system in FIG. 1. For example, the upsampling tool 36 in FIG. 1 may non-transitorily store therein one or more computer program. The computer program may include one or more instructions. When the one or more instructions is loaded into the working memory 30, the one or more instructions may cause the processor 10 to perform the operation/method according to various embodiments of the present disclosure. That is, the processor 10 may perform operations/methods according to various embodiments of the present disclosure by executing one or more loaded instructions.

For example, when the instructions in the computer program non-transitorily stored in the upsampling tool 36 are executed by the processor, the instructions cause the processor to: obtain a first dataset including a plurality of first measurement points, a first measurement value at each of the plurality of first measurement points, and a plurality of first variables other than the first measurement value; generate a second dataset based on the first dataset, wherein the second dataset includes a plurality of second measurement points and a plurality of second variables other than a second measurement value at each of the plurality of second measurement points, wherein the plurality of second measurement points are different from the plurality of first measurement points, wherein the second measurement value is in an unmeasured state; and input the second dataset into an upsampling model to estimate the second measurement value.

Furthermore, when the instructions in the computer program non-transitorily stored in the upsampling tool 36 are executed by the processor, the instructions cause the processor to: obtain a plurality of datasets, wherein each of the datasets includes a plurality of measurement points, a measurement value at each of the plurality of measurement points, and a plurality of variables other than the measurement value; and train the upsampling model to estimate a measurement value corresponding to any measurement point, using the plurality of datasets as training data.

Although the above-described embodiments have been described mainly as related to overlay measurement and related correction, the present disclosure is not limited thereto. Embodiments of the present disclosure may be used for all types of measurements that require high-density measurement points during the semiconductor manufacturing process. Furthermore, the numeric variables, ordinal variables, and categorical variables that may affect the measurement may be configured to be suitable for the corresponding measurement. For example, other types of measurements excluding overlay measurement may include critical dimension (CD) measurement, thickness measurement, bright field (BF) measurement, and dark field (DF) measurement.

According to an embodiment of the present disclosure, the model may learn the relationship between the actually measured measurement value, the exposure information, the substrate process information, and the measurement value based on the exposure information and the substrate process information, and may estimate the unmeasured measurement value, based on the relationship. Further, the model may generate the higher density measurement points than that of the actually measured measurement points, and corresponding measurement values. According to embodiments of the present disclosure, the accuracy and uniformity of the semiconductor manufacturing process may be improved, and thus the performance and reliability of the manufactured semiconductor devices may be improved, and the efficiency of the semiconductor manufacturing process may be increased.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

Various embodiments of the present disclosure and the effects according to those embodiments have been mentioned above with reference to FIGS. 1 to 9. The effects according to the technical idea of the present disclosure are not limited to the effects as mentioned above, and other effects not mentioned may be clearly understood by those skilled in the art from the above descriptions.

All the components that constitute the embodiment of the present disclosure are described as being combined with each other or operating in combination with each other. However, the present disclosure is not necessarily limited to this embodiment. In other words, within the scope of the purpose of the present disclosure, all of the components may operate in a selective combination manner of at least two thereof with each other.

Although the operations are shown as being executed in a specific order in the drawings, it should not be understood that the operations should be performed in the specific order as shown or in a sequential order or that all illustrated operations should be performed to obtain the desired result.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A method of upsampling measurement points in a semiconductor process,
wherein the method is performed by a computing device,
wherein the method comprises:
obtaining a first dataset including a plurality of first measurement points, a plurality of first measurement values corresponding to the plurality of first measurement points, and a plurality of first variables representing information of the semiconductor process other than the plurality of first measurement values;
generating a second dataset based on the first dataset, wherein the second dataset includes a plurality of second measurement points and a plurality of second variables, wherein the plurality of second measurement points are different from the plurality of first measurement points; and
inputting the second dataset into an upsampling model to estimate a plurality of second measurement values corresponding to the plurality of second measurement points,
wherein the plurality of second variables represent information of the semiconductor process other than the plurality of second measurement values,
wherein the plurality of first variables include a numeric variable, an ordinal variable, and a categorical variable related to the plurality of first measurement values, and
wherein the plurality of second variables include a numeric variable, an ordinal variable, and a categorical variable related to the plurality of second measurement values.

2. The method of claim 1,
wherein a density of the plurality of second measurement points is greater than a density of the plurality of first measurement points.

3. The method of claim 1,
wherein each of the first dataset and the second dataset is related to overlay measurement.

4. The method of claim 3, further comprising calculating an overlay correction value and an overlay residual using the second dataset.

5. The method of claim 3, further comprising:
integrating the first dataset and the second dataset with each other into a third dataset; and
calculating an overlay correction value and an overlay residual using the third dataset.

6. The method of claim 3,
wherein the numeric variable includes at least one of a measurement position on a substrate, a position of an exposure field, a substrate leveling value at the measurement position, and a Z2XY value based on a differential value of the substrate leveling value,
wherein the ordinal variable includes at least one of a field exposure order, a substrate exposure order, and
wherein the categorical variable includes at least one of a measurement date, a product information, an exposure layer, an exposure date, an exposure equipment name, a measurement equipment name, a substrate ID, an exposure direction, a field row number, a field column number, and a measurement direction.

7. The method of claim 1,
wherein the upsampling model is configured to estimate the plurality of second measurement values using a decision tree algorithm and a light gradient boosting machine (LGBM) algorithm based on the second dataset.

8. A method of training an upsampling model for upsampling measurement points in a semiconductor process, wherein the method is performed by a computing device,
wherein the method comprises:
obtaining a plurality of datasets, wherein each of the plurality of datasets includes a plurality of measurement points, a plurality of measurement values corresponding to the plurality of measurement points, and a plurality of variables representing information of the semiconductor process other than the plurality of measurement values; and
training the upsampling model to estimate a measurement value corresponding to any measurement point, using the plurality of datasets as training data,
wherein the plurality of datasets are related to the semiconductor process, and
wherein the plurality of variables include a numeric variable, an ordinal variable, and a categorical variable related to the plurality of measurement values.

9. The method of claim 8,
wherein the training of the upsampling model includes:
determining a first dataset to be used for training the upsampling model from among the plurality of datasets;
adjusting a plurality of hyperparameters of the upsampling model; and
performing a k-fold cross-validation technique on the first dataset, and
wherein the performing of the k-fold cross-validation technique includes:
splitting the first dataset into k equally sized subsets corresponding to k folds;
training the upsampling model on (k−1) folds and validating the upsampling model on the remaining fold;
repeating k times the training and the validating, each time using a different fold as a validation set and the rest as a training set; and
averaging performance metric across all folds to generate an estimate of the upsampling model's performance.

10. The method of claim 9,
wherein the adjusting of the plurality of hyperparameters includes adjusting the plurality of hyperparameters using at least one of grid search, random search, and Bayesian search.

11. The method of claim 8,
wherein the plurality of datasets are related to overlay measurement.

12. The method of claim 11,
wherein the numeric variable includes at least one of a measurement position on a substrate, a position of an exposure field, a substrate leveling value at the measurement position, and a Z2XY value based on a differential value of the substrate leveling value,
wherein the ordinal variable includes at least one of a field exposure order, a substrate exposure order, and
wherein the categorical variable includes at least one of a measurement date, a product information, an exposure layer, an exposure date, an exposure equipment name, a measurement equipment name, a substrate ID, an exposure direction, a field row number, a field column number, and a measurement direction.

13. The method of claim 8,
wherein the training of the upsampling model includes training the upsampling model to estimate the measurement value corresponding to any measurement point, using a decision tree algorithm and a light gradient boosting machine (LGBM) algorithm based on the plurality of datasets.

14. A system for upsampling measurement points in a semiconductor process, the system comprising:
a processor; and
a memory for storing instructions therein,
wherein when the instructions are executed by the processor, the instructions cause the processor to:
obtain a first dataset including a plurality of first measurement points, a plurality of first measurement values corresponding to the plurality of first measurement points, and a plurality of first variables other than the plurality of first measurement values;
generate a second dataset based on the first dataset, wherein the second dataset includes a plurality of second measurement points and a plurality of second variables, wherein the plurality of second measurement points are different from the plurality of first measurement points; and
input the second dataset into an upsampling model to estimate a plurality of second measurement values corresponding to the plurality of second measurement points,
wherein the plurality of second variables represent information of the semiconductor process other than the plurality of second measurement values,
wherein the plurality of first variables include a numeric variable, an ordinal variable, and a categorical variable related to the plurality of first measurement values, and
wherein the plurality of second variables include a numeric variable, an ordinal variable, and a categorical variable related to the plurality of second measurement values.

15. The system of claim 14,
wherein a density of the plurality of second measurement points is greater than a density of the plurality of first measurement points.

16. The system of claim 14,
wherein each of the first dataset and the second dataset is related to overlay measurement.

17. The system of claim 16,
wherein when the instructions are executed by the processor, the instructions further cause the processor to calculate an overlay correction value and an overlay residual using the second dataset.

18. The system of claim 16,
wherein when the instructions are executed by the processor, the instructions further cause the processor to:
integrate the first dataset and the second dataset with each other into a third dataset; and
calculate an overlay correction value and an overlay residual using the third dataset.

19. The system of claim 16,
wherein the numeric variable includes at least one of a measurement position on a substrate, a position of an exposure field, a substrate leveling value at the measurement position, and a Z2XY value based on a differential value of the substrate leveling value,
wherein the ordinal variable includes at least one of a field exposure order, a substrate exposure order, and
wherein the categorical variable includes at least one of a measurement date, a product, an exposure layer, an exposure date, an exposure equipment name, a measurement equipment name, a substrate ID, an exposure direction, a field row number, a field column number, and a measurement direction.

20. The system of claim 14,
wherein the upsampling model is configured to estimate the plurality of second measurement values using a decision tree algorithm and a light gradient boosting machine (LGBM) algorithm based on the second dataset.
